(19) United States
(12) Patent Application Publication
(10) Pub. No.: US 2026/0147393 A1
(43) Pub. Date: May 28, 2026

(54) MANAGING A THERMAL STATE OF HARDWARE

(71) Applicant: Dell Products L.P., Round Rock, TX (US)

(72) Inventors: YAYUN LIU, Austin, TX (US); MIN GONG, Shanghai (CN)

(21) Appl. No.: 18/962,740

(22) Filed: Nov. 27, 2024

(51) Int. Cl. G06F 1/20; H05K 7/20

(52) U.S. Cl. CPC G06F 1/206; H05K 7/20136; H05K 7/20209

(57) ABSTRACT

Methods and systems for managing operation of a data processing system are disclosed. The operation may be managed by managing a thermal state of at least one hardware component. To manage the thermal state, an adapter of a management controller may facilitate communication between a thermal manager of the management controller and at least one sensor. During passthrough mode, the adapter may transmit a first request to and receive first temperature data from a first at least one sensor. During active mode, the adapter may transmit a second request to and receive operational data from a second at least one sensor. The adapter may use an inference model to generate second temperature data. The thermal manager may use either the first temperature data and/or the second temperature data to optimize performance of the at least one hardware component.

### FIELD

Embodiments disclosed herein relate generally to managing operation of a data

processing system. More particularly, embodiments disclosed herein relate to managing a thermal state of at least one hardware component of a data processing system.

### BACKGROUND

Computing devices may provide computer-implemented services. The computer-implemented

services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in

the figures of the accompanying drawings in which like references indicate similar elements.

FIG. 1A shows a diagram illustrating a system in accordance with an embodiment.

FIG. 1B shows a diagram illustrating a portion of a system in accordance with an embodiment.

FIGS. 2A-2B show interaction diagrams illustrating operation of a system in accordance with an embodiment.

FIG. 2C shows a data flow diagram illustrating operation of a system in accordance with an embodiment.

FIGS. 3A-3E show flow diagrams illustrating at least one method in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to managing operation of a data processing system. The operation may be managed by managing a thermal state of at least one hardware component of a data processing system.

The thermal state of at least one hardware component may be managed by including an adapter alongside a thermal manager in a management controller of a data processing system. The thermal manager may optimize performance of the at least one hardware component by adjusting at least one parameter of the at least one hardware component. The at least one parameter may include a fan speed, a cooling unit, a voltage scaling, a clock speed, an airflow direction, etc.

The adapter may direct at least one request, by the thermal manager, for temperature data. The adapter may operate in one of two modes: passthrough mode and/or active mode.

During passthrough mode, the adapter may transmit a first health check request from the thermal manager to a first at least one sensor. If the first at least one sensor responds to the first health check request, then the thermal manager may send a first temperature data request to the first at least one sensor through the adapter. The first at least one sensor may respond by recording first temperature data from the at least one hardware component. The first temperature data may be transmitted by the first at least one sensor through the adapter to the thermal manager. Using the first temperature data, the thermal manager may optimize performance of the at least one hardware component.

The adapter may transmit a second health check request from the thermal manager to a first at least one sensor. If the first at least one sensor does not respond to the second health check request, then the adapter may deactivate passthrough mode and activate active mode.

During active mode, the thermal manager may send a second temperature data request to a second at least one sensor through the adapter. The second at least one sensor may respond by recording operational data from a second at least one hardware component. The operational data may include temperatures, power consumption metrics, duty cycles, fan speeds, throughput rates, read/write speeds, thermal throttling events, etc. of a second at least one hardware component (e.g., network interface card, power supply unit, storage drive, central/graphical processing unit (CPU/GPU), etc.). The second at least one sensor may transmit the operational data to the adapter.

The adapter may use a trained temperature inference model to generate second temperature data. The trained temperature inference model may ingest the operational data of the second at least one hardware component to generate second temperature data of the at least one hardware component. The adapter may transmit the second temperature data to the thermal manager. Using the second temperature data, the thermal manager may optimize performance of the at least one hardware component.

In an embodiment, a method for operation of a data processing system is disclosed. The method may include: (i) making an identification that a temperature sensor is unable to provide temperature data used in managing thermal operation of the data processing system; (ii) obtaining, based on the identifying and using at least a trained inference model, inferred temperature data for the temperature sensor; and (iii) setting, based on the inferred temperature data, operation of at least one cooling component of the data processing system to retain temperatures of hardware components of the data processing system within predefined thermal ranges to facilitate provisioning of computer implemented services by the data processing system.

The method may further include obtaining second temperature data from a second temperature sensor of the data processing system, wherein the second temperature data is used by the trained inference model to provide the inferred temperature data.

The method may further include obtaining at least one power metric from at least one power supply unit of the data processing system, wherein the at least one power metric is used by the trained inference model to provide the inferred temperature data.

The method may further include obtaining at least one duty cycle of at least one fan of the data processing system, wherein the at least one duty cycle is used by the trained inference model to provide the inferred temperature data.

The method may further include obtaining at least one measure of airflow direction of at least one system exhaust of the data processing system, wherein the at least one measure of the airflow direction is used by the trained inference model to provide the inferred temperature data.

Setting the operation may include ingesting the inferred temperature data into a closed loop control algorithm to obtain an operating point for the at least one cooling component; and using the operating point in the setting of the operation.

The closed loop control algorithm does not take into account an operating state of the temperature sensor.

In an embodiment, a non-transitory media is provided. The non-transitory media may include instructions that when executed by a processor cause the computer-implemented method to be performed.

In an embodiment, a data processing system is provided. The data processing system may include the non-transitory media and a processor, and may perform the computer-implemented method when the computer instructions are executed by the processor.

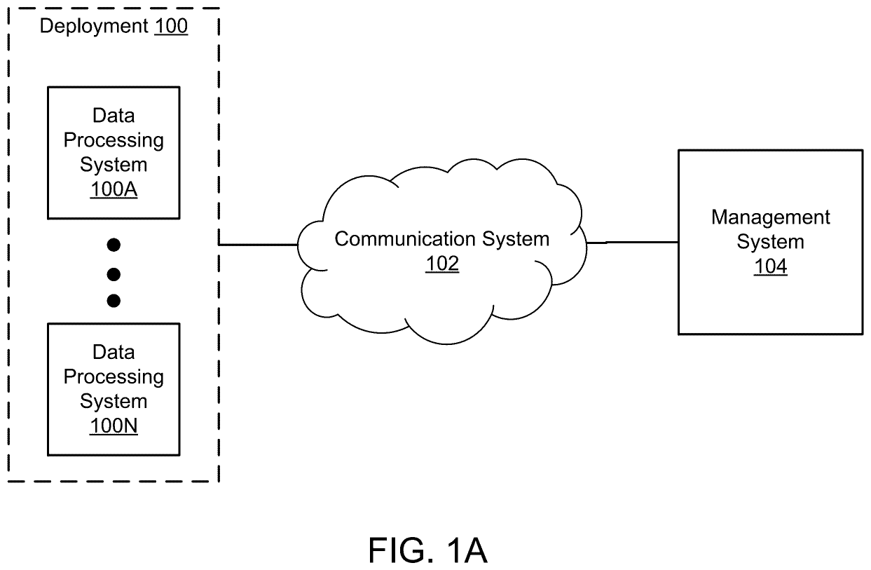

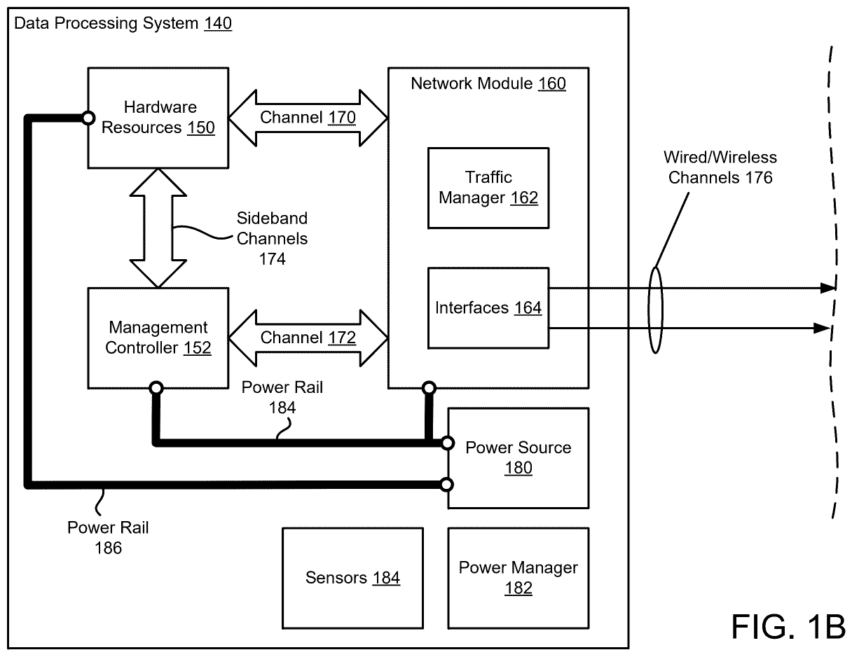

Turning to FIG. 1A, a system in accordance with an embodiment is shown. The system may provide any number and types of computer implemented services (e.g., to user of the system and/or devices operably connected to the system). The computer implemented services may include, for example, data storage service, instant messaging services, etc.

To provide the computer implemented services, a management controller may obtain temperature data from at least one sensor in a data processing system. The management controller may obtain the temperature data by receiving the temperature data from the at least one sensor. The temperature data may be used by the management controller to monitor a thermal state of at least one hardware component of the data processing system. Based on the temperature data, the management controller may optimize performance of the at least one hardware component by (i) adjusting at least one fan speed, (ii) activating at least one cooling unit, (iii) reducing a clock speed of the at least one hardware component, (iv) redistributing a workload across multiple processors to prevent overheating, etc.

However, the management controller may fail to obtain the temperature data. The management controller may fail to obtain the temperature data because an operation of the at least one sensor may fail. The operation of the at least one sensor may fail because (i) the at least one sensor may be defective and/or damaged, (ii) a connection between the at least one sensor and/or the management controller may be disrupted, (iii) exposure to extreme temperatures, humidity, and/or physical damage can impair a performance of the at least one sensor, etc. Due to the failure to obtain the temperature data by the management controller from the at least one sensor, the management controller may not be able to monitor the thermal state of the at least one hardware component of the data processing system. Because the management controller may not be able to monitor the thermal state, computer implemented services may be impacted.

In general, embodiments disclosed here relate to systems and methods for managing operation of a data processing system. The operation of the data processing system may be managed by facilitating communication between a management controller of the data processing system and a first at least one sensor that sends temperature data to the management controller. The communication may be facilitated by an adapter. The adapter may be software that is included in the management controller.

The adapter may have at least two modes: a passthrough mode and/or an active mode. In a first instance, during passthrough mode, a thermal manager of the management controller of the data processing system may transmit a first at least one request for first temperature data to the adapter of the management controller. The adapter may receive the first at least one request and transmit the first at least one request to the first at least one sensor. The first at least one sensor may receive the first at least one request.

In response to the at least one request, the first at least one sensor may transmit the first temperature data to the adapter. The adapter may receive the first temperature data and transmit the first temperature data to the thermal manager. The thermal manager may receive the first temperature data. Based on the first temperature data, the thermal manager may optimize performance of a first at least one hardware component by (i) adjusting at least one fan speed, (ii) activating at least one cooling unit, (iii) reducing a clock speed of the at least one hardware component, (iv) redistributing a workload across multiple processors to prevent overheating, etc.

In a second instance, during passthrough mode, the thermal manager may transmit a second at least one request for second temperature data to the adapter. The adapter may receive the second at least one request and transmit the second at least one request to the first at least one sensor. The first at least one sensor may not respond. The first at least one sensor may not respond because (i) the first at least one sensor may be defective and/or damaged, (ii) a connection between the first at least one sensor and/or the management controller may be disrupted, (iii) exposure to extreme temperatures, humidity, and/or physical damage can impair a performance of the first at least one sensor, etc.

Because the first at least one sensor did not respond, the adapter may deactivate passthrough mode and activate active mode. During active mode, the adapter may no longer transmit the second at least one request to the first at least one sensor. Instead, the adapter may transmit the second at least one request to a second at least one sensor.

The second at least one sensor may receive the second at least one request. Based on the second at least one request, the second at least one sensor may obtain operational data. The operational data from the second at least one sensor may include temperatures, power consumption metrics, duty cycles, fan speeds, throughput rates, read/write speeds, thermal throttling events, etc. of a second at least one hardware component (e.g., network interface card, power supply unit, storage drive, central/graphical processing unit (CPU/GPU), etc.). Then, the second at least one sensor may send the operational data to the adapter.

The adapter may receive the operational data. The adapter may transmit the operational data to an inference model. The inference model may be a trained temperature inference model. The trained temperature inference model may be trained to generate second temperature data based on operational data from a second at least one sensor. The trained temperature inference model may ingest the operational data and, based on the operational data, may output second temperature data.

The trained temperature inference model may transmit the second temperature data to the adapter. The adapter may receive the second temperature data. The adapter may transmit the second temperature data to the thermal manager. The thermal manager may receive the second temperature data. Based on the second temperature data, the thermal manager may optimize performance of the first at least one hardware component by (i) adjusting at least one fan speed, (ii) activating at least one cooling unit, (iii) reducing a clock speed of the at least one hardware component, (iv) redistributing a workload across multiple processors to prevent overheating, etc.

To provide the above noted functionality, the system may include deployment 100, and management system 104. Each of these components is discussed below.

Deployment 100 may include any number of data processing system 100A-100N and may include a power supply unit to power data processing system 100A-100N. Data processing system 100A-100N may include hardware components such as GPUs/CPUs, a motherboard, storage device, etc. Data processing system 100A-100N may also include a management controller.

The management controller, shown in FIG. 1B, may include an adapter and/or a thermal manager. The adapter may facilitate transmission of first temperature data, received from a first temperature sensor, and/or second temperature data, received from a trained temperature inference model. The first temperature data may be measured from a first at least one hardware component. The second temperature data may be inferred by the trained temperature inference model based on operational data of a second at least one hardware component. The operational data from the second at least one sensor may include temperatures, power consumption metrics, duty cycles, fan speeds, throughput rates, read/write speeds, thermal throttling events, etc. of the second at least one hardware component (e.g., network interface card, power supply unit, storage drive, central/graphical processing unit (CPU/GPU), etc.).

Receiving either the first temperature data and/or the second temperature data from the adapter, the thermal manager may monitor performance of the first at least one hardware component. Based on the first temperature data and/or the second temperature data, the thermal manager may optimize performance of the at least one hardware component by (i) adjusting at least one fan speed, (ii) activating at least one cooling unit, (iii) reducing a clock speed of the at least one hardware component, (iv) redistributing a workload across multiple processors to prevent overheating, etc.

Management system 104 may train an inference model to generate the trained temperature inference model. Management system 104 may train the inference model by (i) collecting the first temperature data for the first at least one hardware component of a data processing system, (ii) collecting the operational data for the second at least one hardware component of the data processing system and (iii) using the first temperature data and the operational data to train the inference model to predict at least one temperature based on at least one operational parameter of the at least one hardware component of the data processing system. The inference model may be trained using (i) supervised learning, (ii) unsupervised learning, (iii) reinforcement learning, etc.

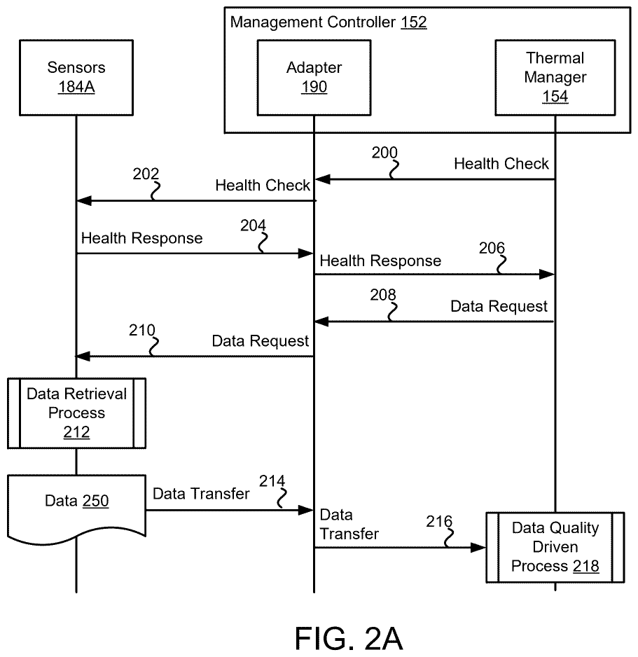

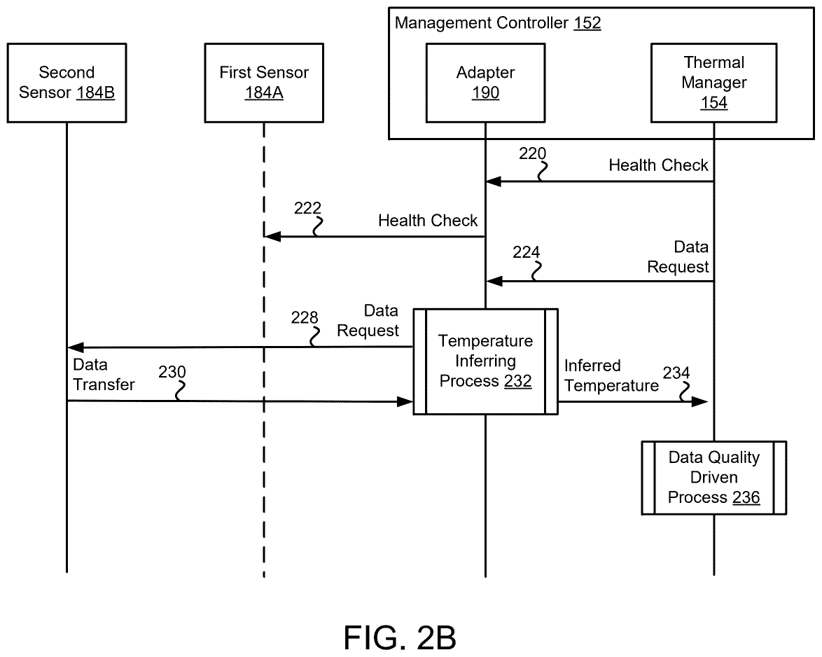

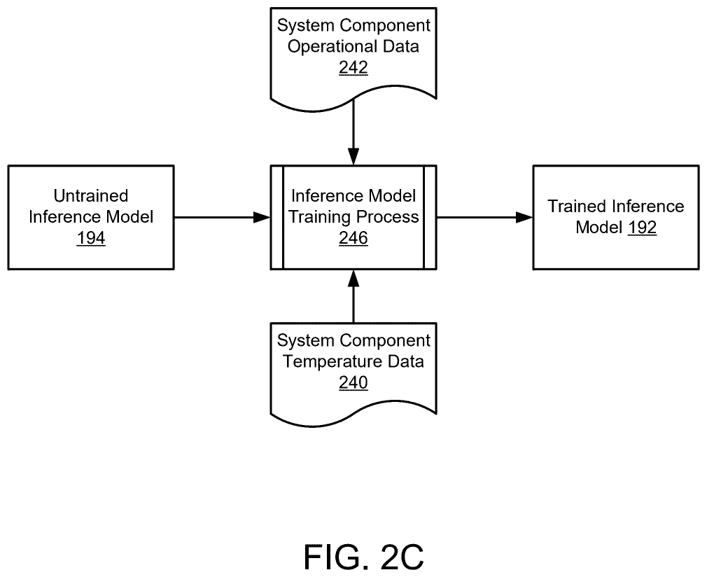

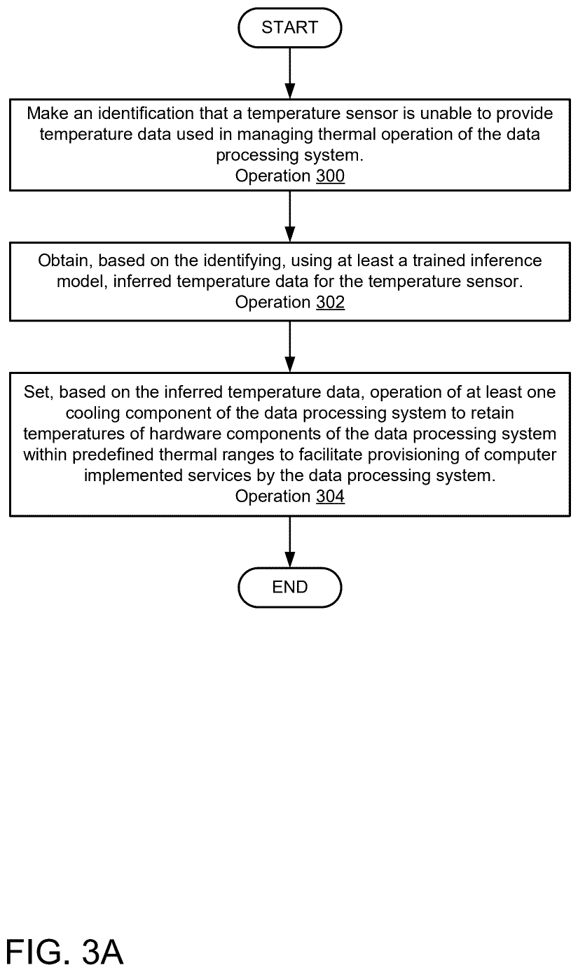

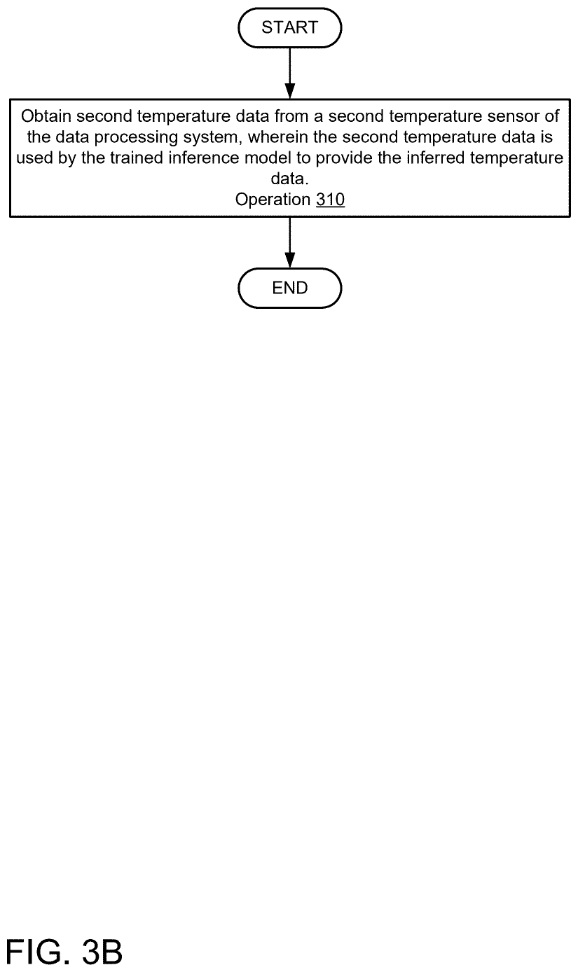

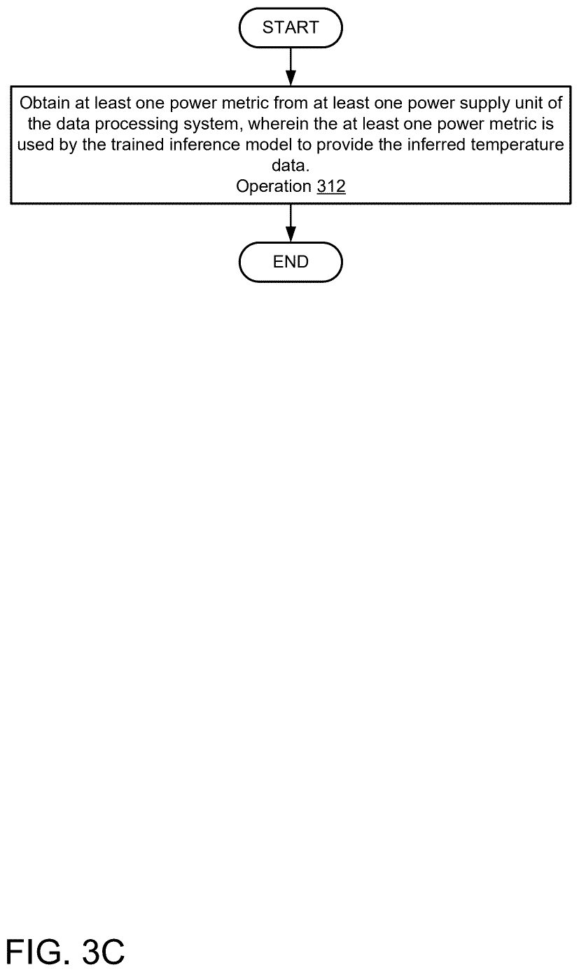

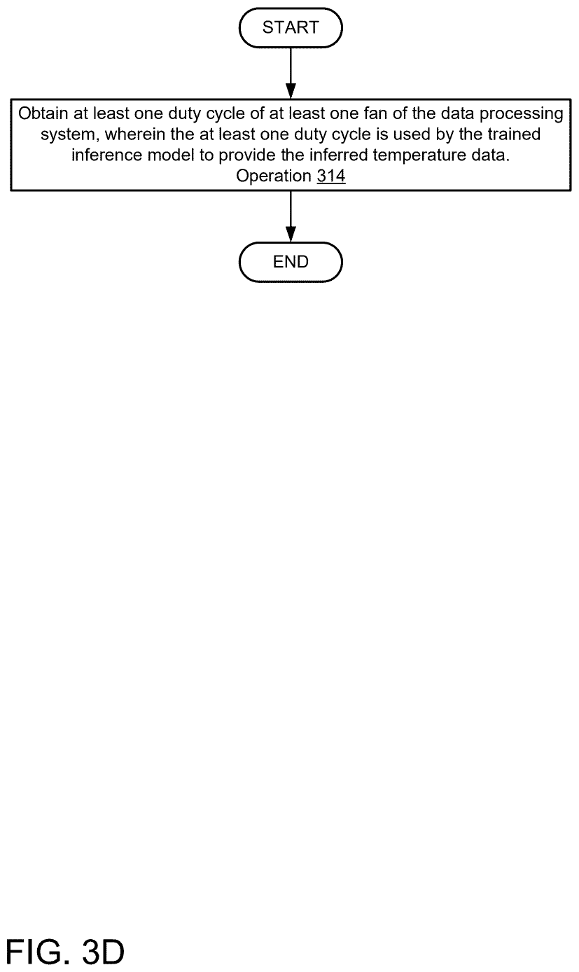

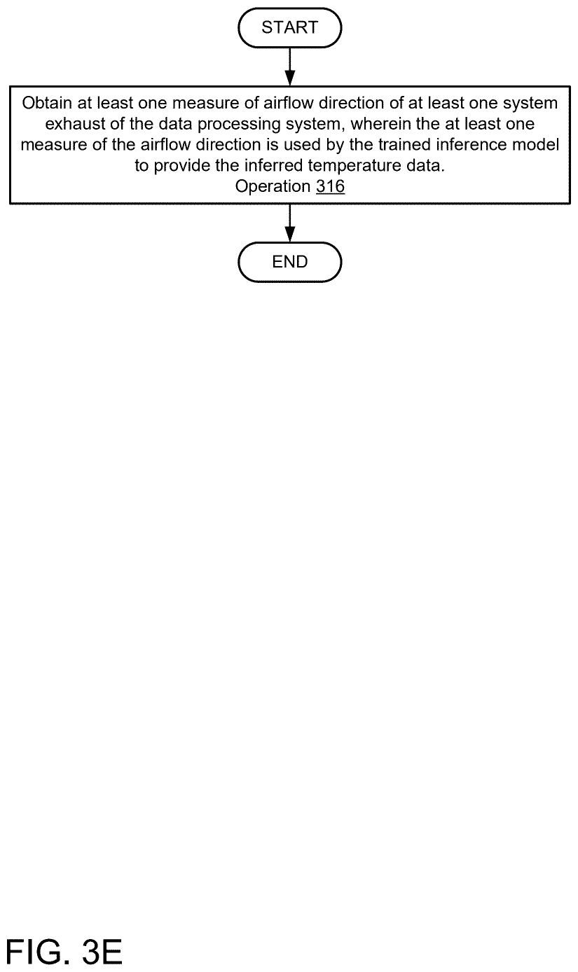

While providing their functionality, any of deployment 100 and management system 104 may perform all, or a portion, of the flows and methods shown in FIGS. 2A-3E.

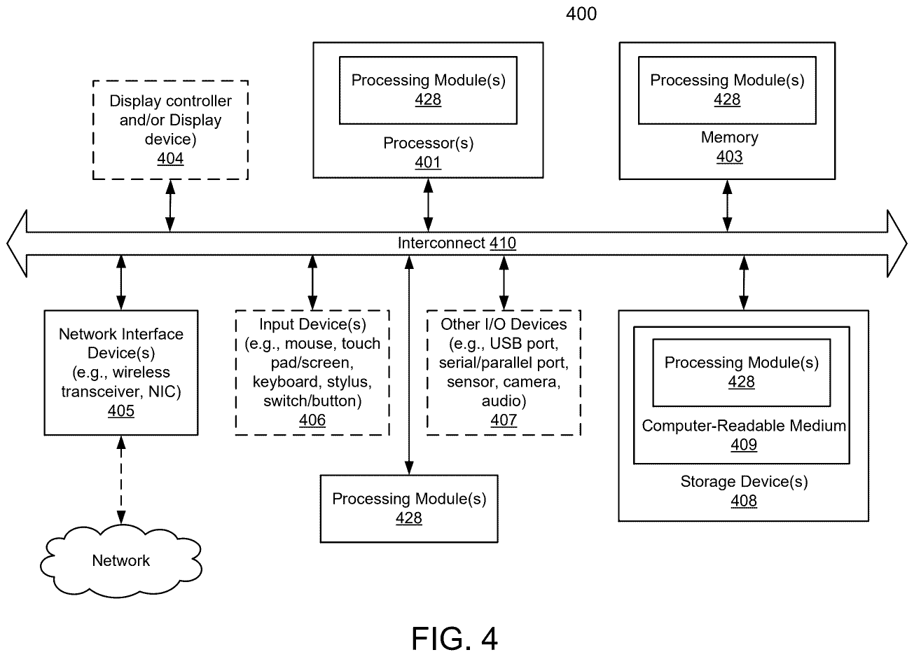

Any of (and/or components thereof) deployment 100 and management system 104 may be implemented using a computing device (also referred to as a data processing system) such as a host or a server, a personal computer (e.g., desktops, laptops, and tablets), a “thin” client, a personal digital assistant (PDA), a Web enabled appliance, a mobile phone (e.g., Smartphone), an embedded system, local controllers, an edge node, and/or any other type of data processing device or system. For additional details regarding computing devices, refer to FIG. 4.

Any of the components illustrated in FIG. 1A may be operably connected to each other (and/or components not illustrated) with communication system 102. In an embodiment, communication system 102 includes one or more networks that facilitate communication between any number of components. The networks may include wired networks and/or wireless networks (e.g., and/or the Internet). The networks may operate in accordance with any number and types of communication protocols (e.g., such as the Internet protocol).

While illustrated in FIG. 1A as including a limited number of specific components, a system in accordance with an embodiment may include fewer, additional, and/or different components than those components illustrated therein.

Turning to FIG. 1B, a diagram illustrating data processing system 140 in accordance with an embodiment is shown. Data processing system 140 may be similar to any of the data processing systems shown in FIG. 1A.

To provide computer implemented services, data processing system 140 may include any quantity of hardware resources 150. Hardware resources 150 may be in-band hardware components, and may include a processor operably coupled to memory, storage, and/or other hardware components.

The processor may host various management entities such as operating systems, drivers, network stacks, and/or other software entities that provide various management functionalities. For example, the operating system and drivers may provide abstracted access to various hardware resources. Likewise, the network stack may facilitate packaging, transmission, routing, and/or other functions with respect to exchanging data with other devices.

For example, the network stack may support transmission control protocol/internet protocol communication (TCP/IP) (e.g., the Internet protocol suite) thereby allowing the hardware resources 150 to communicate with other devices via packet switched networks and/or other types of communication networks.

The processor may also host various applications that provide the computer implemented services. The applications may utilize various services provided by the management entities and use (at least indirectly) the network stack to communication with other entities.

However, use of the network stack and the services provided by the management entities may place the applications at risk of indirect compromise. For example, if any of these entities trusted by the applications are compromised, these entities may subsequently compromise the operation of the applications. For example, if various drivers and/or the communication stack are compromised, communications to/from other devices may be compromised. If the applications trust these communications, then the applications may also be compromised.

For example, to communicate with other entities, an application may generate and send communications to a network stack and/or driver, which may subsequently transmit a packaged form of the communication via channel 170 to a communication component, which may then send the packaged communication (in a yet further packaged form, in some embodiments, with various layers of encapsulation being added depending on the network environment outside of data processing system 140) to another device via any number of intermediate networks (e.g., via wired/wireless channels 176 that are part of the networks).

To reduce the likelihood of the applications and/or other in-band entities from being indirectly compromised, data processing system 140 may include management controller 152 and network module 160. Each of these components of data processing system 140 is discussed below.

Management controller 152 may be implemented, for example, using a system on a chip or other type of independently operating computing device (e.g., independent from the in-band components, such as hardware resources 150, of data processing system 140). Management controller 152 may provide various management functionalities for data processing system 140. For example, management controller 152 may monitor various ongoing processes performed by the in-band component, may manage power distribution, thermal management, and/or other functions of data processing system 140.

To do so, management controller 152 may be operably connected to various components via sideband channels 174 (in FIG. 1B, a limited number of sideband channels are included for illustrative purposes, it will be appreciated that management controller 152 may communication with other components via any number of sideband channels). The sideband channels may be implemented using separate physical channels, and/or with a logical channel overlay over existing physical channels (e.g., logical division of in-band channels). The sideband channels may allow management controller 152 to interface with other components and implement various management functionalities such as, for example, general data retrieval (e.g., to snoop ongoing processes), telemetry data retrieval (e.g., to identify a health condition/other state of another component), function activation (e.g., sending instructions that cause the receiving component to perform various actions such as displaying data, adding data to memory, causing various processes to be performed), and/or other types of management functionalities.

For example, to reduce the likelihood of indirect compromise of an application hosted by hardware resources 150, management controller 152 may enable information from other devices to be provided to the application without traversing the network stack and/or management entities of hardware resources 150. To do so, the other devices may direct communications including the information to management controller 152. Management controller 152 may then, for example, send the information via sideband channels 174 to hardware resources 150 (e.g., to store it in a memory location accessible by the application, such as a shared memory location, a mailbox architecture, or other type of memory-based communication system) to provide it to the application. Thus, the application may receive and act on the information without the information passing through potentially compromised entities. Consequently, the information may be less likely to also be compromised, thereby reducing the possibility of the application becoming indirectly compromised. Similarly processes may be used to facilitate outbound communications from the applications.

Management controller 152 may be operably connected to communication components of data processing system 140 via separate channels (e.g., 172) from the in-band components, and may implement or otherwise utilize a distinct and independent network stack (e.g., TCP/IP). Consequently, management controller 152 may communication with other devices independently of any of the in-band components (e.g., does not rely on any hosted software, hardware components, etc.). Accordingly, compromise of any of hardware resources 150 and hosted component may not result in indirect compromise of any management controller 152, and entities hosted by management controller 152.

To facilitate communication with other devices, data processing system 140 may include network module 160. Network module 160 may provide communication services for in-band components and out-of-band components (e.g., management controller 152) of data processing system. To do so, network module 160 may include traffic manager 162 and interfaces 164.

Traffic manager 162 may include functionality to (i) discriminate traffic directed to various network endpoints advertised by data processing system 140, and (ii) forward the traffic to/from the entities associated with the different network endpoints. For example, to facilitate communications with other devices, network module 160 may advertise different network endpoints (e.g., different media access control address/internet protocol addresses) for the in-band components and out-of-band components. Thus, other entities may address communications to these different network endpoints. When such communications are received by network module 160, traffic manager 162 may discriminate and direct the communications accordingly (e.g., over channel 170 or channel 172, in the example shown in FIG. 1B, it will be appreciated that network module 160 may discriminate traffic directed to any number of data units and direct it accordingly over any number of channels).

Accordingly, traffic directed to management controller 152 may never flow through any of the in-band components. Likewise, outbound traffic from the out-of-band component may never flow through the in-band components.

To support inbound and outbound traffic, network module 160 may include any number of interfaces 164. Interfaces 164 may be implemented using any number and type of communication devices which may each provide wired and/or wireless communication functionality. For example, interfaces 164 may include a wide area network card, a WiFi card, a wireless local area network card, a wired local area network card, an optical communication card, and/or other types of communication components. These component may support any number of wired/wireless channels 176.

Thus, from the perspective of an external device, the in-band components and out-of-band components of data processing system 140 may appear to be two independent network entities, that may independently addressable, and otherwise unrelated to one another.

To facilitate management of data processing system 140 over time, hardware resources 150, management controller 152 and/or network module 160 may be positioned in separately controllable power domains. By being positioned in these separately power domains, different subsets of these components may remain powered while other subsets are unpowered.

For example, management controller 152 and network module 160 may remain powered while hardware resources 150 is unpowered. Consequently, management controller 152 may remain able to communication with other devices even while hardware resources 150 are inactive. Similarly, management controller 152 may perform various actions while hardware resources 150 are not powered and/or are otherwise inoperable, unable to cooperatively perform various process, are compromised, and/or are unavailable for other reasons.

To implement the separate power domains, data processing system 140 may include a power source (e.g., 180) that separately supplies power to power rails (e.g., 184, 186) that power the respective power domains. Power from the power source (e.g., a power supply, battery, etc.) may be selectively provided to the separate power rails to selectively power the different power domains. A power manager (e.g., 182) may manage power from power source 180 is supplied to the power rails. Management controller 152 may cooperate with power manager 182 to manage supply of power to these power domains.

In FIG. 1B, an example implementation of separate power domains using power rails 184-186 is shown. The power rails may be implemented using, for example, bus bars or other types of transmission elements capable of distributing electrical power. While not shown, it will be appreciated that the power domains may include various power management components (e.g., fuses, switches, etc.) to facilitate selective distribution of power within the power domains.

Further, management controller 152 may collect telemetry data from hardware resources 150. Management controller 152 may collect telemetry data by receiving the telemetry data from hardware resources 150 through sideband channels 174. Hardware resources 150 may include hardware within data processing system 140.

To send the telemetry data to management system 104, management controller 152 may send the telemetry data by channel 172 to network module 160. Network module 160 may include interface 164, by which the telemetry data may be sent. The telemetry data may be sent through wired/wireless channels 176 to management system 104.

In FIG. 1B, sensors 184 may be included in data processing system 140. A first sensor of sensors 184 may monitor a thermal state of a first at least one hardware component. The first sensor may detect a temperature of the first at least one hardware component using a thermocouple, a thermistor, a solid-state device, etc. The first sensor may convert the temperature to an electrical signal (e.g., a measure of voltage, etc.) that is proportional to the temperature. The electrical signal may be sent to management controller 152 using a communication protocol (e.g., inter-integrated circuit, system management bus, etc.).

In addition, a second sensor of sensors 184 may monitor an operational state of a second at least one hardware component to obtain operational data. The operational data from may include temperatures, power consumption metrics, duty cycles, fan speeds, throughput rates, read/write speeds, thermal throttling events, etc. of the second at least one hardware component (e.g., network interface card, power supply unit, storage drive, central/graphical processing unit (CPU/GPU), etc.). The operational data may be used by a trained temperature inference model to infer the temperature of the first at least one hardware component. The sensor may convert the operational data to an electrical signal (e.g., a measure of voltage). The electrical signal may be sent to management controller 152 using a communication protocol (e.g., inter-integrated circuit, system management bus, etc.).

To further clarify embodiments disclosed herein, interactions diagrams in accordance with an embodiment are shown in FIGS. 2A-2B. These interactions diagrams may illustrate how data may be obtained and used within the system of FIG. 2A-2B.

In the interaction diagrams, processes performed by and interactions between components of a system in accordance with an embodiment are shown. In the diagrams, components of the system are illustrated using a first set of shapes (e.g., 184A, 190, etc.), located towards the top of each figure. Lines descend from these shapes. Processes performed by the components of the system are illustrated using a second set of shapes (e.g., 212, 218, etc.) superimposed over these lines. Interactions (e.g., communication, data transmissions, etc.) between the components of the system are illustrated using a third set of shapes (e.g., 200, 202, etc.) that extend between the lines. The third set of shapes may include lines terminating in one or two arrows. Lines terminating in a single arrow may indicate that one way interactions (e.g., data transmission from a first component to a second component) occur, while lines terminating in two arrows may indicate that multi-way interactions (e.g., data transmission between two components) occur.

Generally, the processes and interactions are temporally ordered in an example order, with time increasing from the top to the bottom of each page. For example, the interaction labeled as 200 may occur prior to the interaction labeled as 202. However, it will be appreciated that the processes and interactions may be performed in different orders, any may be omitted, and other processes or interactions may be performed without departing from embodiments disclosed herein.

Turning to FIG. 2A, a first interaction diagram in accordance with an embodiment is shown. The first interaction diagram may illustrate data used in and data processing performed in performing, by an adapter of the management controller, a passthrough mode.

To perform, by the adapter, the passthrough mode, a thermal manager (e.g., 154) of the management controller may transmit (e.g., 200) a first health check request to the adapter (e.g., 190). The thermal manager (e.g., 154) may transmit (e.g., 200) the first health check request by sending a first message through an inter-process communication method. The inter-process communication method may include shared memory, sockets, message queues, etc. The first health check request may be a first query for a first status update concerning functionality of a first at least one sensor (e.g., 184A).

The adapter (e.g., 190) may receive (e.g., 200) the first health check from the thermal manager (e.g., 154). The adapter (e.g., 190) may then transmit (e.g., 202) the first health check request to the first at least one sensor (e.g., 184A). The adapter (e.g., 190) may transmit (e.g., 202) the first health check request by sending the first message using the inter-process communication method. The inter-process communication method may include shared memory, sockets, message queues, etc.

The first at least one sensor (e.g., 184A) may receive (e.g., 202) the first health check from the adapter (e.g., 190). In response to the first health check, the first at least one sensor (e.g., 184A) may transmit (e.g., 204) a first health response to the adapter (e.g., 190). The first at least one sensor (e.g., 184A) may transmit the (e.g., 200) by sending a second message using the inter-process communication method. The inter-process communication method may include shared memory, sockets, message queues, etc. The first health response may include the first status update concerning the functionality of the first at least one sensor (e.g., 184A).

The adapter (e.g., 190) may receive (e.g., 204) the first health response from the first at least one sensor (e.g., 184A). By receiving (e.g., 204) the first health response, the adapter (e.g., 190) may confirm that the first at least one sensor (e.g., 184A) is in a functional state and/or can perform a transmission of a message and/or data. The adapter (e.g., 190) may then transmit (e.g., 206) the first health response to the thermal manager (e.g., 154). The adapter (e.g., 190) may transmit (e.g., 206) the first health response by sending the second message using the inter-process communication method. The inter-process communication method may include shared memory, sockets, message queues, etc.

The thermal manager (e.g., 154) may receive (e.g., 206) the first health response from the adapter (e.g., 190). By receiving (e.g., 206) the first health response, the thermal manager (e.g., 154) may also confirm that that the first at least one sensor (e.g., 184A) is in a functional state and/or can perform a transmission of the message and/or the data. The thermal manager (e.g., 154) may, with a frequency of time, send another health check request to the first at least one sensor (e.g., 184A).

At some point after receiving the first health response, the thermal manager (e.g., 154) may transmit (e.g., 208) a first temperature data request to the adapter (e.g., 190). The thermal manager (e.g., 154) may transmit (e.g., 208) the first temperature data request by sending a third message using the inter-process communication method. The inter-process communication method may include shared memory, sockets, message queues, etc.

The adapter (e.g., 190) may receive (e.g., 208) the first temperature data request from the thermal manager (e.g., 154). Because the adapter (e.g., 190) has confirmed that the first at least one sensor (e.g., 184A) is in a functional state and/or can perform the transmission of the message and/or the data, the adapter (e.g., 190) may transmit the first temperature data request (e.g., 210) to the first at least one sensor (e.g., 184A). The adapter (e.g., 190) may transmit (e.g., 210) the first temperature data request by sending the third message using the inter-process communication method. The inter-process communication method may include shared memory, sockets, message queues, etc.

The first at least one sensor (e.g., 184A) may receive (e.g., 210) the first temperature data request from the adapter (e.g., 190). Once the first temperature data request has been received (e.g., 210) by the first at least one sensor (e.g., 184A), data retrieval process 212 may be performed.

During data retrieval process 212, the first at least one sensor (e.g., 184A) may collect first temperature data (e.g., 250). The first at least one sensor (e.g., 184A) may collect first temperature data by (i) recording, for a period of time, the first temperature data of a first at least one hardware component of a data processing system and/or (ii) retrieving the first temperature data that has been recorded and/or cached by the first at least one sensor (e.g., 184A).

The first temperature data (e.g., 250) may include a measure of at least one thermal state of the first at least one hardware component. The measure of the at least one thermal state may include a series of temperature values over the period of the time. The temperature values over the period of the time may be recorded, for example, as a series of key and/or value pairs. For the key and/or value pair of the key and/the value pairs, a time may be set as the key and/or the temperature value may be set at the value.

After data retrieval process 212 has been performed and the first temperature data (e.g., 250) has been retrieved, the first at least one sensor (e.g., 184) may respond (e.g., 210) to the first temperature data request. The first at least one sensor (e.g., 184) may respond by transmitting (e.g., 214) the first temperature data to the adapter (e.g., 190). The first temperature data may be transmitted (e.g., 214) using the inter-process communication method. The inter-process communication method may include shared memory, sockets, message queues, etc.

The adapter (e.g., 190) may receive (e.g., 214) the first temperature data (e.g., 250). Upon receiving the first temperature data (e.g., 250), the adapter (e.g., 190) may transmit (e.g., 216) the first temperature data (e.g., 250) to the thermal manager (e.g., 154). The adapter (e.g., 190) may transmit (e.g., 216) the first temperature data (e.g., 250) using the inter-process communication method. The inter-process communication method may include shared memory, sockets, message queues, etc.

The thermal manager (e.g., 154) may receive (e.g., 216) the first temperature data (e.g., 250). Upon receiving, by the thermal manager (e.g., 154), the first temperature data (e.g., 250), data quality driven process 218 may be performed. During data quality driven process 218, the thermal manager (e.g., 154) may (i) perform an analysis of the first temperature data of the at least one thermal state of the first at least one hardware component and/or (ii) optimize performance of the first at least one hardware component based on the at least one thermal state of the at least one hardware component.

The thermal manager (e.g., 154) may perform the analysis by, for example, identifying at least one variation and/or at least one pattern in the first temperature data (e.g., 250) to determine the at least one thermal state of the first at least one hardware component. The thermal manager (e.g., 154) may optimize performance the first at least one hardware component by, for example, (i) adjusting at least one fan speed, (ii) activating at least one cooling unit, (iii) reducing a clock speed, (iv) redistributing a workload across multiple processors to prevent overheating, etc.

Thus, via the interaction illustrated in FIG. 2A, a system in accordance with an embodiment may perform, by an adapter of the management controller, the passthrough mode. Consequently, a deployment (e.g., 100) may be more likely to be able to provide desired computer implemented services by facilitating, by the adapter (e.g., 190), communication for and transmission of the first temperature data (e.g., 250) between the thermal manager (e.g., 154) and the first at least one sensor (e.g., 184A) for optimization of the performance of the first at least one hardware component in the data processing system.

Turning to FIG. 2B, a second interaction diagram in accordance with an embodiment is shown. The second interaction diagram may illustrate data used in and data processing performed in performing, by an adapter of the management controller, an active mode.

To perform, by the adapter, the active mode, a thermal manager (e.g., 154) of the management controller may transmit (e.g., 220) a second health check request to the adapter (e.g., 190). The thermal manager (e.g., 154) may transmit (e.g., 220) the second health check request by sending a fourth message through an inter-process communication method. The inter-process communication method may include shared memory, sockets, message queues, etc. The second health check request may be a second query for a second status update concerning functionality of the first at least one sensor (e.g., 184A).

The adapter (e.g., 190) may receive (e.g., 220) the second health check from the thermal manager (e.g., 154). The adapter (e.g., 190) may then transmit (e.g., 222) the second health check request to the first at least one sensor (e.g., 184A). The adapter (e.g., 190) may transmit (e.g., 222) the second health check request by sending the fourth message using the inter-process communication method. The inter-process communication method may include shared memory, sockets, message queues, etc. The first at least one sensor (e.g. 184A) may not receive the second health check because the first at least one sensor (e.g., 184A) has a failure in operation. The operation of the first at least one sensor (e.g., 184A) may fail because (i) the at least one sensor may be defective and/or damaged, (ii) a connection between the at least one sensor and/or the management controller may be disrupted, (iii) exposure to extreme temperatures, humidity, and/or physical damage can impair a performance of the at least one sensor, etc.

Because of the failure in operation experienced by the first at least one sensor (e.g., 184A), after a period of time has passed, the adapter (e.g., 190) may consider the first at least one sensor to be non-functional. As a result, the adapter (e.g., 190) may deactivate passthrough mode and activate active mode.

In active mode, the thermal manager (e.g., 154) may transmit (e.g., 224) an operational data request to the adapter (e.g., 190). The thermal manager (e.g., 154) may transmit (e.g., 224) the operational data request by sending a fifth message using the inter-process communication method. The inter-process communication method may include shared memory, sockets, message queues, etc.

The adapter (e.g., 190) may receive (e.g., 224) the operational data request from the thermal manager (e.g., 154). Once the operational data request has been received by the adapter (e.g., 190), temperature inferring process 232 may be performed.

During temperature inferring process 232, the adapter (e.g., 190) may transmit (e.g., 228) the operational data request to a second at least one sensor (e.g., 184B). The adapter (e.g., 190) may transmit (e.g., 228) the operational data request by sending the fifth message using the inter-process communication method. The inter-process communication method may include shared memory, sockets, message queues, etc.

The second at least one sensor (e.g., 184B) may receive (e.g., 228) the operational data request from the adapter (e.g., 190). Once the operational data request has been received by the second at least one sensor (e.g., 184B), the second at least one sensor (e.g., 184B) may collect operational data. The second at least one sensor (e.g., 184B) may collect operational data by (i) recording, for a period of time, the operational data of a second at least one hardware component of a data processing system and/or (ii) retrieving the operational data that has been recorded and/or cached by the second at least one sensor (e.g., 184B).

The operational data may include temperatures, power consumption metrics, duty cycles, fan speeds, throughput rates, read/write speeds, thermal throttling events, etc. of the second at least one hardware component (e.g., network interface card, power supply unit, storage drive, central/graphical processing unit (CPU/GPU), etc.). At least one value of the operational data over the period of the time may be recorded, for example, as a series of key and/or value pairs. For the key and/or value pair of the key and/or the value pairs, a time may be set as the key and/or the operational data value may be set at the value.

After the operational data has been retrieved, the second at least one sensor (e.g., 184B) may respond (e.g., 230) to the operational data request. The second at least one sensor (e.g., 184B) may respond by transmitting (e.g., 230) the operational data to the adapter (e.g., 190). The operational data may be transmitted (e.g., 230) using the inter-process communication method. The inter-process communication method may include shared memory, sockets, message queues, etc.

The adapter (e.g., 190) may receive (e.g., 230) the operational data from the second at least one sensor (e.g., 184B). Once the operational data has been received by the adapter (e.g., 190), temperature inferring process 232 may be continued.

During temperature inferring process 232, the second temperature data may be generated by a trained temperature inference model. The second temperature data may be generated by (i) ingesting, by the trained temperature inference model, the operational data of the second at least one hardware component and (ii) determining, using the operational data, the second temperature data of the first at least one hardware component that was mentioned in the description of FIG. 2A. The second temperature data may be determined by using, by the trained temperature inference model, at least one correlation and/or at least one pattern between operation of the second at least one hardware component and at least one thermal state of the first at least one hardware component to make at least one temperature prediction of the first at least one hardware component.

Once the second temperature data has been generated, the adapter (e.g., 190) may transmit (e.g., 234) the second temperature data to the thermal manager (e.g., 154). The adapter (e.g., 190) may transmit (e.g., 234) the second temperature data using the inter-process communication method. The inter-process communication method may include shared memory, sockets, message queues, etc.

Once the thermal manager (e.g., 154) has received the second temperature data, data quality driven process 236 may be performed. Data quality driven process 236 may be performed similarly to data quality driven process 218 in the description of FIG. 2A.

Thus, via the interaction illustrated in FIG. 2B, a system in accordance with an embodiment may perform, by an adapter of the management controller, the active mode. Consequently, a deployment (e.g., 100) may be more likely to be able to provide desired computer implemented services by facilitating, by the adapter (e.g., 190), communication for, generation, and transmission of the second temperature data between the thermal manager (e.g., 154) and the second at least one sensor (e.g., 184B) for optimization of the performance of the first at least one hardware component in the data processing system.

To further clarify embodiments disclosed herein, a data flow diagram in accordance with an embodiment is shown in FIG. 2C. In these diagrams, flows of data and processing of data are illustrated using different sets of shapes. A first set of shapes (e.g., 240, 242, etc.) is used to represent data structures and a second set of shapes (e.g., 246, etc.) is used to represent processes performed using and/or that generate data.

Turning to FIG. 2C, a first data flow diagram in accordance with an embodiment is shown. The first data flow diagram may illustrate data used in and data processing performed in generation of a trained temperature inference model.

To generate the trained temperature inference model, inference model training process 246 may be performed. During inference model training process 246, untrained inference model 194, system component operational data 242, and system component temperature data 240 may be ingested.

Untrained inference model 194 may include an inference model that has not yet ingested data with which to learn at least one pattern and/or at least one relationship. Since the at least one pattern and/or the at least one relationship has not been established by untrained inference model 194, any data generated by untrained inference model 194 may be based on random weights, biases, and/or gradients.

System component temperature data 240 may similar to first temperature data from a first description of FIG. 2A. System component temperature data 240 may include temperature data from a first at least one hardware component. The temperature data may be recorded for a period of time to describe at least one thermal state of the first at least one hardware component.

System component operational data 242 may be similar to operational data from the description of FIG. 2B. The operational data may include data recorded from a second at least one hardware component of a data processing system. The operational data may include temperatures, power consumption metrics, duty cycles, fan speeds, throughput rates, read/write speeds, thermal throttling events, etc. of the at least one hardware component (e.g., network interface card, power supply unit, storage drive, central/graphical processing unit (CPU/GPU), etc.).

During inference model training process 246, trained inference model 192 may be generated. Trained inference model 192 may be similar to the trained temperature inference model in the description of FIG. 2B. To generate trained inference model 192, a model architecture may be selected with which to train untrained inference model 194. The model architecture may include supervised learning, unsupervised learning, reinforcement learning, etc. Then, system component operational data 242 and system component temperature data 240 may be ingested by untrained inference model 194. Weights, biases, and/or gradients of untrained inference model 194 may be adjusted to search for at the at least one pattern and/or the at least one relationship between system component operational data 242 and system component temperature data 240. As a result of adjusting the weights, the biases, and/or the gradients, trained inference model 192 may be generated. A separate validation set that includes a first at least one portion of system component operational data 242 and a second at least one portion of system component temperature data 240 may be used to assess a performance of trained inference model 192. Based on at least one result of the performance, at least one hyperparameter (e.g., learning rate, epochs, layers, neurons, activation function, etc.) may be adjusted to improve the performance. Once the performance of at least one prediction by trained inference model 192 is determined to be satisfactory, trained inference model 192 may be deployed.

Trained inference model 192 may be used to predict temperature data of the first at least one hardware component based on the operational data generated by a the second at least one hardware component. For example, a first operational data may include a series of clock speeds, throttle events, power consumptions, etc. of a central processing unit (CPU). Trained inference model 192 may ingest the first operational data of the CPU to generate first inferred temperature data of a graphical processing unit (GPU). Trained inference model 192 may account for the possibility that a heavy utilization of the CPU by a data processing system may generate significant heat, which can indirectly affect a temperature of the GPU in a data processing system. The first inferred temperature data may be used by a thermal manager of the data processing system to enforce proactive measures by a cooling system of the data processing system to prevent the CPU from overheating.

Thus, via the data flow illustrated in FIG. 2C, a system in accordance with an embodiment may generate a trained temperature inference model. Consequently, a deployment (e.g., 100) may be more likely to be able to provide desired computer implemented services by generating, using the trained temperature inference model, inferred temperature data; the inferred temperature data may be provided to the thermal manager of a data processing system for optimization of performance of the first at least one hardware component.

Any of the processes illustrated using the second set of shapes and interactions illustrated using the third set of shapes may be performed, in part or whole, by digital processors (e.g., central processors, processor cores, etc.) that execute corresponding instructions (e.g., computer code/software). Execution of the instructions may cause the digital processors to initiate performance of the processes. Any portions of the processes may be performed by the digital processors and/or other devices. For example, executing the instructions may cause the digital processors to perform actions that directly contribute to performance of the processes, and/or indirectly contribute to performance of the processes by causing (e.g., initiating) other hardware components to perform actions that directly contribute to the performance of the processes.

Any of the processes illustrated using the second set of shapes and interactions illustrated using the third set of shapes may be performed, in part or whole, by special purpose hardware components such as digital signal processors, application specific integrated circuits, programmable gate arrays, graphics processing units, data processing units, and/or other types of hardware components. These special purpose hardware components may include circuitry and/or semiconductor devices adapted to perform the processes. For example, any of the special purpose hardware components may be implemented using complementary metal-oxide semiconductor based devices (e.g., computer chips).

Any of the processes and interactions may be implemented using any type and number of data structures. The data structures may be implemented using, for example, tables, lists, linked lists, unstructured data, data bases, and/or other types of data structures. Additionally, while described as including particular information, it will be appreciated that any of the data structures may include additional, less, and/or different information from that described above. The informational content of any of the data structures may be divided across any number of data structures, may be integrated with other types of information, and/or may be stored in any location.

As discussed above, the components of FIGS. 1A-1B may perform various methods to manage operation of a data processing system. FIG. 3A illustrates a method that may be performed by the components of the system of FIGS. 1A-1B. In the diagram discussed below and shown in FIG. 3A, any of the operations may be repeated, performed in different orders, and/or performed in parallel with or in a partially overlapping in time manner with other operations.

Turning to FIG. 3A, a flow diagram illustrating a method of managing operation of a data processing system in accordance with an embodiment is shown. The method may be performed, for example, by any of the components of the system of FIGS. 1A-1B, and/or other components not shown therein.

At operation 300, an identification may be made that a temperature sensor is unable to provide temperature data used in managing thermal operation of the data processing system. The identification may be made by receiving, by an adapter of a management controller, no response from the temperature sensor after the adapter transmitted a health check request to the temperature sensor.

At operation 302, inferred temperature data may be obtained, using at least a trained inference model, for the temperature sensor. The inferred temperature data may be obtained by generating, by the trained inference model, the inferred temperature data. The inferred temperature data may be generated based on ingesting, by the trained inference model, operational data from at least one hardware component of the data processing system. The operational data may include temperatures, power consumption metrics, duty cycles, fan speeds, throughput rates, read/write speeds, thermal throttling events, etc. of the at least one hardware component (e.g., network interface card, power supply unit, storage drive, central/graphical processing unit (CPU/GPU), etc.).

At operation 304, the operation may be set, based on the inferred temperature data, of at least one cooling component of the data processing system to retain temperatures of hardware components of the data processing system within predefined thermal ranges to facilitate provisioning of computer implemented services by the data processing system. The operation may be set by (i) ingesting the inferred temperature data into a closed loop control algorithm to obtain an operating point for the at least one cooling component; and (ii) using the operating point in the setting of the operation.

The inferred temperature data may be ingested by reading, by a thermal manager of the management controller, the inferred temperature data. The operating point may be used by adjusting at least one parameter of the at least one cooling component to set the operation.

The method may end following operation 304.

Thus, via the method shown in FIG. 3A, embodiments herein may likely improve a likelihood of managing operation of a data processing system. By improving the likelihood of managing operation of a data processing system, the data processing system may be more likely to provide desirable computer implemented services by, for example, generating the inferred temperature data of a first at least one hardware component when a temperature sensor is non-functional, utilizing the inferred temperature data to set the operating point of the at least one cooling component, etc.

As discussed above, the components of FIGS. 1A-1B may perform various methods to manage operation of a data processing system. FIG. 3B illustrates a method that may be performed by the components of the system of FIGS. 1A-1B. In the diagram discussed below and shown in FIG. 3B, any of the operations may be repeated, performed in different orders, and/or performed in parallel with or in a partially overlapping in time manner with other operations.

Turning to FIG. 3B, a flow diagram illustrating a method of managing operation of a data processing system in accordance with an embodiment is shown. The method may be performed, for example, by any of the components of the system of FIGS. 1A-1B, and/or other components not shown therein.

At operation 310, second temperature data may be obtained from a second temperature sensor of the data processing system, wherein the second temperature data is used by the trained inference model to provide the inferred temperature data. The second temperature data may be obtained by receiving, by an adapter of a management controller, the second temperature data from the second temperature sensor. The adapter may provide the second temperature data to a trained inference model. The inferred temperature data of a first at least one hardware component may be generated based on ingesting, by the trained inference model, the second temperature data of a second at least one hardware component of the data processing system.

The method may end following operation 310.

Thus, via the method shown in FIG. 3B, embodiments herein may likely improve a likelihood of managing operation of a data processing system. By improving the likelihood of managing operation of a data processing system, the data processing system may be more likely to provide desirable computer implemented services by, for example, using the second temperature data of the second at least one hardware component to generate the inferred temperature data of the first at least one hardware component of the data processing system, etc.

As discussed above, the components of FIGS. 1A-1B may perform various methods to manage operation of a data processing system. FIG. 3C illustrates a method that may be performed by the components of the system of FIGS. 1A-1B. In the diagram discussed below and shown in FIG. 3C, any of the operations may be repeated, performed in different orders, and/or performed in parallel with or in a partially overlapping in time manner with other operations.

Turning to FIG. 3C, a flow diagram illustrating a method of managing operation of a data processing system in accordance with an embodiment is shown. The method may be performed, for example, by any of the components of the system of FIGS. 1A-1B, and/or other components not shown therein.

At operation 312, at least one power metric may be obtained from at least one power supply unit of the data processing system, wherein the at least one power metric is used by the trained inference model to provide the inferred temperature data. The at least one power metric may be obtained by receiving, by an adapter of a management controller, the at least one power metric from the at least one power supply unit. The adapter may provide the at least one power metric to a trained inference model. The inferred temperature data of a first at least one hardware component may be generated based on ingesting, by the trained inference model, the at least one power metric of the at least one power supply unit of the data processing system.

The method may end following operation 312.

Thus, via the method shown in FIG. 3C, embodiments herein may likely improve a likelihood of managing operation of a data processing system. By improving the likelihood of managing operation of a data processing system, the data processing system may be more likely to provide desirable computer implemented services by, for example, using the at least one power metric of the at least one power supply unit to generate the inferred temperature data of the first at least one hardware component of the data processing system, etc.

As discussed above, the components of FIGS. 1A-1B may perform various methods to manage operation of a data processing system. FIG. 3D illustrates a method that may be performed by the components of the system of FIGS. 1A-1B. In the diagram discussed below and shown in FIG. 3D, any of the operations may be repeated, performed in different orders, and/or performed in parallel with or in a partially overlapping in time manner with other operations.

Turning to FIG. 3D, a flow diagram illustrating a method of managing operation of a data processing system in accordance with an embodiment is shown. The method may be performed, for example, by any of the components of the system of FIGS. 1A-1B, and/or other components not shown therein.

At operation 314, at least duty cycle may be obtained from at least one fan of the data processing system, wherein the at least one duty cycle is used by the trained inference model to provide the inferred temperature data. The at least one duty cycle may be obtained by receiving, by an adapter of a management controller, the at least one duty cycle from the at least one fan. The adapter may provide the at least one duty cycle to a trained inference model. The inferred temperature data of a first at least one hardware component may be generated based on ingesting, by the trained inference model, the at least one duty cycle of the at least one fan of the data processing system.

The method may end following operation 314.

Thus, via the method shown in FIG. 3D, embodiments herein may likely improve a likelihood of managing operation of a data processing system. By improving the likelihood of managing operation of a data processing system, the data processing system may be more likely to provide desirable computer implemented services by, for example, using the at least one duty cycle of the at least one fan to generate the inferred temperature data of the first at least one hardware component of the data processing system, etc.

As discussed above, the components of FIGS. 1A-1B may perform various methods to manage operation of a data processing system. FIG. 3E illustrates a method that may be performed by the components of the system of FIGS. 1A-1B. In the diagram discussed below and shown in FIG. 3E, any of the operations may be repeated, performed in different orders, and/or performed in parallel with or in a partially overlapping in time manner with other operations.

Turning to FIG. 3E, a flow diagram illustrating a method of managing operation of a data processing system in accordance with an embodiment is shown. The method may be performed, for example, by any of the components of the system of FIGS. 1A-1B, and/or other components not shown therein.

At operation 316, at least one measure of airflow direction may be obtained from at least one system exhaust of the data processing system, wherein the at least measure of the airflow direction is used by the trained inference model to provide the inferred temperature data. The at least one measure of the airflow direction may be obtained by receiving, by an adapter of a management controller, the at least measure of the airflow direction from the at least one system exhaust. The adapter may provide the at least measure of the airflow direction to a trained inference model. The inferred temperature data of a first at least one hardware component may be generated based on ingesting, by the trained inference model, the at least one measure of the airflow direction of the at least one system exhaust of the data processing system.

The method may end following operation 316.

Thus, via the method shown in FIG. 3E, embodiments herein may likely improve a likelihood of managing operation of a data processing system. By improving the likelihood of managing operation of a data processing system, the data processing system may be more likely to provide desirable computer implemented services by, for example, using the at least one measure of the airflow direction of the at least one system exhaust to generate the inferred temperature data of the first at least one hardware component of the data processing system, etc.

Any of the components illustrated in FIGS. 1A-2C may be implemented with one or more computing devices. Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a WiFi transceiver, an infrared transceiver, a Bluetooth transceiver, a WiMax transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as a keyboard or thermal sensor may be controlled by an embedded controller (not shown), dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components; as such details are not germane to embodiments disclosed herein. It will also be appreciated that network computers, handheld computers, mobile phones, servers, and/or other data processing systems which have fewer components or perhaps more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A method for managing operation of a data processing system, the method comprising:
making an identification that a temperature sensor is unable to provide temperature data used in managing thermal operation of the data processing system;
based on the identifying:
obtaining, using at least a trained inference model, inferred temperature data for the temperature sensor; and
setting, based on the inferred temperature data, operation of at least one cooling component of the data processing system to retain temperatures of hardware components of the data processing system within predefined thermal ranges to facilitate provisioning of computer implemented services by the data processing system.

2. The method of claim 1, further comprising:
obtaining second temperature data from a second temperature sensor of the data processing system, wherein the second temperature data is used by the trained inference model to provide the inferred temperature data.

3. The method of claim 1, further comprising:
obtaining at least one power metric from at least one power supply unit of the data processing system, wherein the at least one power metric is used by the trained inference model to provide the inferred temperature data.

4. The method of claim 1, further comprising:
obtaining at least one duty cycle of at least one fan of the data processing system, wherein the at least one duty cycle is used by the trained inference model to provide the inferred temperature data.

5. The method of claim 1, further comprising:
obtaining at least one measure of airflow direction of at least one system exhaust of the data processing system, wherein the at least one measure of the airflow direction is used by the trained inference model to provide the inferred temperature data.

6. The method of claim 1, wherein setting the operation comprises:
ingesting the inferred temperature data into a closed loop control algorithm to obtain an operating point for the at least one cooling component; and
using the operating point in the setting of the operation.

7. The method of claim 6, wherein the closed loop control algorithm does not take into account an operating state of the temperature sensor.

8. A non-transitory machine-readable medium having instructions stored therein, which when executed by a processor, cause the processor to perform operations for managing operation of a data processing system, the operations comprising:
making an identification that a temperature sensor is unable to provide temperature data used in managing thermal operation of the data processing system;
based on the identifying:
obtaining, using at least a trained inference model, inferred temperature data for the temperature sensor; and
setting, based on the inferred temperature data, operation of at least one cooling component of the data processing system to retain temperatures of hardware components of the data processing system within predefined thermal ranges to facilitate provisioning of computer implemented services by the data processing system.

9. The non-transitory machine-readable medium of claim 8, wherein the operations further comprise:
obtaining second temperature data from a second temperature sensor of the data processing system, wherein the second temperature data is used by the trained inference model to provide the inferred temperature data.

10. The non-transitory machine-readable medium of claim 8, wherein the operations further comprise:
obtaining at least one power metric from at least one power supply unit of the data processing system, wherein the at least one power metric is used by the trained inference model to provide the inferred temperature data.

11. The non-transitory machine-readable medium of claim 8, wherein the operations further comprise:
obtaining at least one duty cycle of at least one fan of the data processing system, wherein the at least one duty cycle is used by the trained inference model to provide the inferred temperature data.

12. The non-transitory machine-readable medium of claim 8, wherein the operations further comprise:
obtaining at least one measure of airflow direction of at least one system exhaust of the data processing system, wherein the at least one measure of the airflow direction is used by the trained inference model to provide the inferred temperature data.

13. The non-transitory machine-readable medium of claim 8, wherein setting the operation comprises:
ingesting the inferred temperature data into a closed loop control algorithm to obtain an operating point for the at least one cooling component; and
using the operating point in the setting of the operation.

14. The non-transitory machine-readable medium of claim 13, wherein the closed loop control algorithm does not take into account an operating state of the temperature sensor.

15. A data processing system, comprising:
a processor; and
a memory coupled to the processor to store instructions, which when executed by the processor, cause the processor to perform operations managing operation of a data processing system, the operations comprising:
making an identification that a temperature sensor is unable to provide temperature data used in managing thermal operation of the data
processing system;
based on the identifying:
obtaining, using at least a trained inference model, inferred temperature data for the temperature sensor; and
setting, based on the inferred temperature data, operation of at least one cooling component of the data processing system to retain temperatures of hardware components of the data processing system within predefined thermal ranges to facilitate provisioning of computer implemented services by the data processing system.

16. The data processing system of claim 15, wherein the operations further comprise:
obtaining second temperature data from a second temperature sensor of the data processing system, wherein the second temperature data is used by the trained inference model to provide the inferred temperature data.

17. The data processing system of claim 15, wherein the operations further comprise:
obtaining at least one power metric from at least one power supply unit of the data processing system, wherein the at least one power metric is used by the trained inference model to provide the inferred temperature data.

18. The data processing system of claim 15, wherein the operations further comprise:
obtaining at least one duty cycle of at least one fan of the data processing system, wherein the at least one duty cycle is used by the trained inference model to
provide the inferred temperature data.

19. The data processing system of claim 15, wherein the operations further comprise:
obtaining at least one measure of airflow direction of at least one system exhaust of the data processing system, wherein the at least one measure of the airflow direction is used by the trained inference model to provide the inferred temperature data.

20. The data processing system of claim 15, wherein setting the operation comprises:
ingesting the inferred temperature data into a closed loop control algorithm to obtain an operating point for the at least one cooling component; and
using the operating point in the setting of the operation.
